(19) United States
(12) Patent Application Publication
(10) Pub. No.: US 2025/0147412 A1
(43) Pub. Date: May 8, 2025

(54) METHOD FOR EXAMINING A BLANK OF A MICROLITHOGRAPHIC PHOTOMASK

(71) Applicant: Carl Zeiss SMT GmbH, Oberkochen (DE)

(72) Inventors: Christof Baur, Darmstadt (DE); Michael Budach, Hanau (DE)

(21) Appl. No.: 18/937,899

(22) Filed: Nov. 5, 2024

(30) Foreign Application Priority Data
Nov. 6, 2023 (DE) 102023130586.7

(51) Int. Cl. G03F 1/84; G03F 1/44

(52) U.S. Cl. CPC G03F 1/84; G03F 1/44

(57) ABSTRACT

A method for examining a blank of a microlithographic photomask, including the steps of:
a) arranging the blank on a first stage of a first examination apparatus such that a first and a second edge of the blank rest against stops of the first stage,
b) ascertaining an examination location on the blank in a first coordinate system with the aid of the first examination apparatus,
c) arranging the blank on a second stage of a second examination apparatus having an image recording unit,
d) recording at least one image of the blank using the image recording unit such that the first and second edge are captured at least in part, and
e) ascertaining a transformation rule on the basis of the first and second edge captured in the at least one image, in order to transform the examination location captured in the first coordinate system into a second coordinate system (142) of the second examination apparatus.

### CROSS-REFERENCE TO RELATED APPLICATION

This application claims priority to German application DE 10 2023 130 586.7, filed on Nov. 6, 2023, which is incorporated by reference in its entirety.

### TECHNICAL FIELD

The present invention relates to a method for examining a blank of a microlithographic photomask.

### BACKGROUND

Microlithography is used to produce microstructured component parts, for example integrated circuits. The microlithography process is carried out using a lithography apparatus, which has an illumination system and a projection system. The image of a mask (reticle or lithography mask) illuminated by use of the illumination system is projected here by use of the projection system onto a substrate, for example a silicon wafer, which is coated with a light-sensitive layer (photoresist) and arranged in the image plane of the projection system, in order to transfer the mask structure to the light-sensitive coating of the substrate.

Mask blanks are processed in order for these to be provided with a respective mask structure. The created mask structure is projected with reduced scale onto the substrate. The mask structures themselves are already very small and have dimensions of a few micrometres to a few nanometers, for example. In order to very accurately produce microstructured components using microlithography, the lithography mask structures must also be manufactured very precisely, and the mask must be free from defects (e.g. defective structures and contaminations). A defect-free lithography mask is also very important because a lithography mask is usually used for multiple exposures. Therefore, lithography masks are examined in regard to defects at great expense. Attempts are then made to repair identified defective structures or to remove contaminations. Defects, too, may be extremely small and have sizes of the order of a few nanometers, for example. Hence, work related to the examination of lithography masks and blanks for lithography masks should be carried out with a high spatial resolution and precision.

### SUMMARY

Against this background, an aspect of the present invention consists in the provision of an improved method for examining a blank of a microlithographic photomask.

Accordingly, a method for examining a blank of a microlithographic photomask is proposed. The method comprises the following steps:
a) arranging the blank on a first stage of a first examination apparatus such that a first and a second edge of the blank rest against stops of the first stage,
b) ascertaining an examination location on the blank in a first coordinate system with the aid of the first examination apparatus,
c) arranging the blank on a second stage of a second examination apparatus having an image recording unit,
d) recording at least one image of the blank using the image recording unit such that the first and second edge are captured at least in part, and
e) ascertaining a transformation rule on the basis of the first and second edge captured in the at least one image, in order to transform the examination location captured in the first coordinate system into a second coordinate system of the second examination apparatus.

In the examination of the photomask blank, the proposed method allows the use of two different examination apparatuses (i.e. the first and second examination apparatus) with different coordinate systems (i.e. the first and second coordinate system). For example, the blank does not have any structures, e.g. also no markers, for reproducibly arranging the blank in the stages (i.e. the first and second stage) of the two examination apparatuses. If there are no structures or markers (“alignment markers”) serving the reproducible arrangement of the blank, or if these are not used, then the proposed method allows the first and second edge of the blank, in the first stage of the first examination apparatus, to rest against stops of the first stage. Moreover, when the blank is arranged in the second stage of the second examination apparatus, a position of the first and second edge of the blank can be ascertained by image processing. This can then be used to ascertain the transformation rule for transforming spatial coordinates from the first coordinate system to the second coordinate system. Consequently, an examination location on the blank (e.g. a defect location) ascertained by use of the first examination apparatus can be converted into the second coordinate system of the second examination apparatus. Hence, an examination location ascertained by use of the first examination apparatus can be examined further by the second examination apparatus (e.g. at a higher spatial resolution in comparison with the first examination apparatus).

Furthermore, the first and second edge of the blank resting against the stops of the first examination apparatus can be any desired edges of the blank. Moreover, the second examination apparatus can also comprise stops serving to rest against edges of the blank. The proposed method does not require stops of the second examination apparatus to rest against the same edges and/or the same position on a corresponding edge as the stops of the first examination apparatus.

The blank is a blank for a lithography mask. For example, the blank is a blank for a transmissive lithography mask for DUV lithography (DUV: “deep ultraviolet,” operating light wavelengths in the range of 30-250 nm) or a blank for a reflective lithography mask for EUV lithography (EUV: “extreme ultraviolet,” operating light wavelengths in the range of 0.1-30 nm, in particular 13.5 nm).

The blank comprises a substrate, for example. For example, the substrate comprises silicon dioxide (SiO₂), e.g. quartz glass, and/or an alternating sequence of molybdenum and silicon layers.

For example, as a rule, the blank does not yet comprise any structures (e.g. no absorber structures or phase-shifting structures) which are projected onto a substrate during the microlithographic process. In particular, the blank also comprises no markers (“alignment markers”) serving the reproducible arrangement of the blank in stages of one or more examination apparatuses.

For example, the blank falls within predetermined tolerances in relation to its external dimensions. For example, the blank falls within predetermined tolerances in relation to its external dimensions according to an international standard for DUV lithography masks and/or EUV lithography masks. For example, the international standard for DUV lithography masks and/or EUV lithography masks is the international standard “SEMI P1” (e.g. SEMI P1 2008 Edition, July 2008) and/or the international standard “SEMI P37” (“Specification for Extreme Ultraviolet Lithography Substrates and Blanks”). Purely by way of example, a 6-inch blank according to the “SEMI P1” standard falls within tolerances regarding width and length of +/−400 μm.

For example, the first examination apparatus is configured to recognize one or more blank defects, for example contaminations. For example, the first examination apparatus is configured to create a list of ascertained positions for the recognized defects. In this case, the examination location ascertained in step b) is a position of a recognized defect, for example.

The first examination apparatus has a spatial resolution in the range of 0.5 μm to 25 μm, for example. The first examination apparatus comprises an image recording device with a spatial resolution in the range of 0.5 μm to 25 μm, for example. In an alternative to that or in addition, the first examination apparatus can also be configured for example to detect blank defects by use of light scattering. In this case, a spatial resolution of the first examination apparatus can also be better than 0.5 μm, e.g. 100 nm or better and/or 50 nm or better.

For example, the first stage comprises one or more elastic elements under tension, in addition to the stops configured to rest against the first and second edge of the blank. For example, the one or more elastic elements press the blank against the stops of the first stage. For example, in step a) a first elastic element under tension is arranged on a third edge of the blank that is opposite the first edge. For example, a second elastic element under tension is arranged on a fourth edge of the blank that is opposite the second edge.

For example, the blank comprises a main extension plane. Furthermore, the first and second edge of the blank are arranged in the main extension plane. In particular, the first and second edge of the blank are edges of the blank that are at an angle to one another, for example (e.g. substantially) perpendicular to one another. For example, the first and second edge are adjacent edges. Should the blank comprise rounded-off and/or chamfered corners, only the rounded-off and/or chamfered corner is arranged between the first and second edge, for example.

In particular, the first coordinate system is a coordinate system of the first examination apparatus. For example, the first and second coordinate system both are right-hand Cartesian coordinate systems. For example, the first and second coordinate system both are two-dimensional coordinate systems. For example, the first and second coordinate system both have an abscissa axis and an ordinate axis, which are arranged perpendicular to one another.

A plurality of examination locations on the blank can also be ascertained in the first coordinate system in step b) with the aid of the first examination apparatus. For example, one or more examination locations are ascertained on a surface of the blank in step b).

In particular, the second examination apparatus comprises the image recording unit. For example, the second stage of the second examination apparatus can also comprise one or more stops serving to rest against the first edge, the second edge, a third edge (e.g. arranged opposite the first edge) and/or a fourth edge (e.g. arranged opposite the second edge) of the blank.

The proposed method renders possible an accurate coordinate transformation from the first to the second coordinate system, e.g. even if stops of the second stage rest against different edges (e.g. the third and fourth edge) of the blank than the stops of the first stage, which rest against the first and second edge of the blank.

The transformation rule is ascertained on the basis of the first and second edge captured in the at least one image. In particular, this allows a position of the first and second edge captured in the at least one image to be ascertained in the second coordinate system of the second examination apparatus.

For example, step e) of the method includes an ascertainment of a position of the first and the second edge, both in the first and second coordinate system, on the basis of image processing for the at least one image.

For example, the transformation rule is a mathematical transformation rule. For example, the transformation rule comprises a transformation matrix and/or affine transformation matrix. For example, the transformation rule comprises a rotation through a rotation angle and/or a translation with a translation vector. The transformation rule for example serves the two-dimensional coordinate transformation between the first and second coordinate system. For example, the transformation rule is used to perform a basis transformation between the first and second coordinate system.

According to one embodiment, the second examination apparatus comprises a scanning microscope apparatus, a scanning electron microscope apparatus, a scanning probe microscope apparatus and/or an atomic force microscope apparatus.

For example, the scanning microscope apparatus, scanning electron microscope apparatus, the scanning probe microscope apparatus and/or atomic force microscope apparatus is configured to record the at least one image of the blank. This can be used to record with high spatial resolution the at least one image of the blank, in which the first and second edge are captured at least in part. Consequently, the position of the first and second edge (and/or a position of reference points on the first and second edge) can be ascertained more accurately, whereby a coordinate transformation by use of the transformation rule is possible with greater accuracy.

In particular, the scanning microscope apparatus comprises a scanning electron microscope (SEM), a scanning probe microscope (SPM), an atomic force microscope (AFM) and/or a scanning tunnelling microscope (STM).

According to a further embodiment, a spatial resolution of the image recording unit of the second examination apparatus is 100 μm or better, 50 μm or better, 30 μm or better, 10 μm or better, 5 μm or better, 1 μm or better, 0.1 μm or better, 50 nm or better, 10 nm or better, 5 nm or better and/or 3 nm or better.

The higher the spatial resolution used to record the at least one image, the more accurately the position of the first and second edge (and/or a position of reference points on the first and second edge) can be ascertained by image processing and hence the more accurately the transformation rule can be ascertained.

According to a further embodiment, one or more defects of the blank are examined in the method. Furthermore, a location of at least one defect of the blank is ascertained in the first coordinate system in step b) with the aid of the first examination apparatus. Further, the ascertained transformation rule serves to transform the location of the at least one defect captured in the first coordinate system into a location in the second coordinate system.

Hence, the location of one or more defects of the blank can be ascertained by use of the first examination apparatus. For example, a list of locations of defects of the blank can be created by use of the first examination apparatus. The location of the one or more defects of the blank ascertained by the first examination apparatus or the ascertained list of locations of defects of the blank can be transmitted to the second examination apparatus, for example.

The defect or the defects can be found more easily by use of the second examination apparatus as a result of the location of the defect or the defects ascertained by the first examination apparatus having been transformed into the second coordinate system of the second examination apparatus by use of the transformation rule.

Furthermore, on the basis of the data transmitted by the first examination apparatus, the defect or the defects can be examined more accurately (e.g. at higher resolution) by use of the second examination apparatus.

According to a further embodiment, the method includes after step e):
recording at least one image of the at least one defect using the image recording unit of the second examination apparatus, wherein the image recording unit is aligned on the basis of the location of the at least one defect which has been transformed into the second coordinate system.

For example, an image detail from the image recording unit is chosen on the basis of the location of the at least one defect, which has been transformed into the second coordinate system. For example, the location of the at least one defect, which has been transformed into the second coordinate system, is centered in the image detail.

For example, the second examination apparatus can also be configured to remove defects (e.g. particles) from a surface of the blank. For example, the second examination apparatus comprises a micromanipulator and/or nanomanipulator serving to move and/or remove particles from the surface of the blank.

According to a further embodiment, the first stage comprises a first, second and third stop. The blank is arranged on the first stage in such a way that the first edge rests against the first and second stop and the second edge rests against the third stop such that a first, second and third reference point of the blank are defined accordingly at contact locations of the first, second and third stops on the first and second edge. Moreover, an image of the blank is recorded in step d) for each reference point, the corresponding reference point being captured in the image. Moreover, the transformation rule is ascertained on the basis of the first, second and third reference points captured in the recorded images.

That is to say, a position of the first and second edge at the three reference points is ascertained on the basis of the recorded images, the three stops of the first examination apparatus being in contact at the said reference points. This is advantageous if the edges (e.g. the first and/or second edge) of the blank have deviations from a straight line (e.g. in relation to the resolution of the second examination apparatus). Consequently, the transformation rule can be ascertained accurately, even in the case where the edges of the blank are not 100% straight (e.g. in relation to the resolution of the second examination apparatus).

In particular, the contact locations at which the first edge of the blank rests against the first and second stop of the first stage of the first examination apparatus accordingly define the first and second reference point of the blank. Furthermore, the contact location at which the second edge of the blank rests against the third stop of the first stage defines the third reference point of the blank.

For example, step e) of the method includes an ascertainment of a respective position of the first, second and third reference point, in each case in the first and second coordinate system, on the basis of image processing for the at least one image.

According to a further embodiment, positions of the first and the second reference point in the second coordinate system are ascertained on the basis of image processing for the corresponding recorded images and/or a position of the third reference point in the second coordinate system is ascertained on the basis of image processing for the corresponding recorded image.

For example, the assumption is made here that the first coordinate system of the first examination apparatus corresponds to a coordinate system of the blank. In other words, the assumption is either made here that the blank is arranged in the first stage in step a) without a deviation in relation to the first coordinate system of the first examination apparatus or that such a deviation is neglected for simplification purposes as it is initially unknown.

According to a further embodiment, the transformation rule comprises a rotation through a rotation angle and/or a translation with a translation vector. Furthermore, the rotation angle is ascertained on the basis of the ascertained position of the first and second reference point in the second coordinate system, and/or vector components of the translation vector are ascertained on the basis of the ascertained position of the third reference point in the second coordinate system and the ascertained position of the first or second reference point in the second coordinate system.

For example, the first coordinate system of the first examination apparatus is twisted relative to the second coordinate system of the second examination apparatus through the rotation angle (e.g. in anticlockwise fashion). That is to say an angle between a straight line arranged parallel to a first abscissa axis of the first coordinate system and a straight line arranged parallel to a second abscissa axis of the second coordinate system corresponds to the rotation angle. Then, the rotation angle can be calculated from a right-angled slope triangle formed from the/a straight line arranged parallel to the first abscissa axis and the/a straight line arranged parallel to the second abscissa axis. For example, the slope triangle is formed such that a length of the opposite side Δy of this right-angled slope triangle is given by the distance between the ordinate positions of the first and second reference point in the second coordinate system. Furthermore, the slope triangle is for example formed such that a length of the adjacent side Δx of this right-angled slope triangle is given by the distance between the abscissa positions of the first and second reference point in the second coordinate system. Moreover, the length of the hypotenuse Δu of the slope triangle is given in particular by the distance between the abscissa positions of the first and second reference point in the first coordinate system.

Consequently, the length of the opposite side Δy of this right-angled slope triangle can be calculated from the distance between the ascertained ordinate positions of the first and second reference point in the second coordinate system.

Furthermore, the length of the adjacent side Δx of this right-angled triangle can be assumed approximately to be the same as a length of the hypotenuse Δu of this right angled triangle if very small rotations are assumed.

For example, the distance between the first and second reference point in the first coordinate system, i.e. the length of the hypotenuse Δu, can be ascertained from construction data of the first examination apparatus ascertained in advance. For example, the construction data of the first examination apparatus ascertained in advance contain a distance, ascertained in advance, between the first and second stop of the first stage of the first examination apparatus. Moreover, the first reference point of the blank corresponds to the first stop of the first stage of the first examination apparatus. Furthermore, the second reference point of the blank corresponds to the second stop of the first stage. Hence, the distance between the first and second reference point of the blank in the first coordinate system can be ascertained on the basis of the distance, ascertained in advance, between the first and second stop of the first stage of the first examination apparatus.

Then, the rotation angle Θ emerges approximately from the arctangent of the quotient of opposite side Δy and adjacent side Δx (with the adjacent side, as described above, being assumed approximately to be the same size as the hypotenuse Δu):

$$tan Θ = \frac{Δ y}{Δ x} \approx \frac{Δ y}{Δ u}$$

Alternatively, the rotation angle Θ also emerges directly from the arcsine of the quotient of opposite side Δy and hypotenuse Δu:

$$sin Θ = \frac{Δ y}{Δ u}$$

Thereupon, the ascertained rotation angle Θ can be used to calculate the distance Δx between the first and second reference point in the second coordinate system on the basis of the cosine of the rotation angle Θ:

Δx=Δu cos θ

Alternatively, the distance Δx between the first and second reference point in the second coordinate system can also be calculated on the basis of Pythagoras' theorem:

$$Δ x = \sqrt{Δ {u}^{2} - Δ {y}^{2}}$$

Optionally, the calculation of the distance Δx between the first and second reference point in the second coordinate system can also be ascertained on the basis of multiple iterations.

In the next calculation step, a position of a first origin of the first coordinate system can then be ascertained in the second coordinate system. What applies in particular is that a first straight line connecting the first origin and the third reference point R3 is arranged perpendicular to a second straight line connecting the first and second reference point R1, R2. In other words, a first vector V1 pointing from the first origin to the third reference point R3 is arranged perpendicular to a second vector V2 pointing from the first reference point R1 to the second reference point R2. What therefore holds true is that the scalar product of the first and second connecting vector is zero:

$$V 1 \cdot V 2 = 0$$

$$( R 3 - 0 ) \cdot ( R 2 - R 1 ) = 0$$

Furthermore, a parametric form of the second connection straight line passing through the first and second reference point R1, R2 can be formulated such that each point on the second connection straight line is assigned a parameter lambda:

$$O = R 1 + λ ( R 2 - R 1 )$$

If this parametric form of the second connection straight line is inserted into the above equation with the scalar product, then the following equation arises:

$$( R 3 - R 1 - λ ( R 2 - R 1 ) ) \cdot ( R 2 - R 1 ) = 0$$

This equation can be solved for lambda, and hence the parameter lambda can be calculated.

The origin O can now be calculated by inserting the parameter lambda ascertained in this way into the above parametric form of the second connection straight line.

According to a further embodiment, the transformation rule includes a transformation matrix according to the following equation:

$$( \begin{matrix}x \\ y \\ 1\end{matrix} ) = ( \begin{matrix}cos Θ & - sin Θ & {t}_{x} \\ sin Θ & cos Θ & {t}_{y} \\ 0 & 0 & 1\end{matrix} ) ( \begin{matrix}u \\ v \\ 1\end{matrix} ) ,$$

where u and v denote coordinates of a location in the first coordinate system, x and y denote coordinates of a location in the second coordinate system, Θ denotes a rotation angle of a rotation of the first coordinate system relative to the second coordinate system, and tₓ and t_{y} denote a translation of the first coordinate system relative to the second coordinate system. In an alternative to that or in addition, the transformation rule includes a rotation through a rotation angle which satisfies the following equation:

$$tan Θ = \frac{Δ y}{Δ x} ,$$

where Θ denotes a rotation angle of a rotation of the first coordinate system relative to the second coordinate system, Δx denotes a difference in the abscissa coordinates of the first and second reference point in the second coordinate system, and Δy denotes a difference in the ordinate coordinates of the first and second reference point in the second coordinate system.

According to a further embodiment, the ascertainment of the transformation rule includes an ascertainment of a coordinate origin of the first coordinate system on the basis of the conditions that
the coordinate origin of the first coordinate system is located on a first straight line on which the first and the second reference point are also located, and
the first straight line is arranged perpendicular to a second straight line, on which the coordinate origin of the first coordinate system and the third reference point are located.

As a result, the coordinate origin of the first coordinate system can be ascertained even in the event of rounded-off and/or chamfered corners of the blank.

In embodiments, steps a) to e) are carried out repeatedly such that it is possible to ascertain an averaged transformation rule.

In embodiments, steps a) to e) are carried out repeatedly, to be precise for a plurality of different first examination apparatuses. In particular, steps a) to e) are carried out (at least once) for each of the plurality of different first examination apparatuses. For example, the plurality of different first examination apparatuses differ from one another in that their stops rest against the blank at different contact locations. Hence, a plurality of different transformation rules are ascertained, and these are subsequently averaged. The averaged transformation rule ascertained thus can then be used for coordinate transformation, independently of which of the plurality of first examination apparatuses is used.

According to a further embodiment, the method includes prior to step a):
arranging the blank on the second stage of the second examination apparatus, and
using the second examination apparatus to create a plurality of markers on the blank in accordance with predetermined nominal positions as per the second coordinate system.

Moreover, positions of the plurality of markers in the first coordinate system are ascertained in step b) with the aid of the first examination apparatus. Furthermore, a correction rule serving to correct the transformation rule is ascertained in step e) on the basis of a deviation between the positions of the markers in the first coordinate system ascertained with the aid of the first examination apparatus and the nominal positions of the markers in the second coordinate system.

Consequently, markers on the blank are created by use of the second examination apparatus (i.e. in the second coordinate system), and these created markers are detected by use of the first examination apparatus (i.e. in the first coordinate system). This can be used to ascertain a transformation rule for transforming the first coordinate system into the second coordinate system. Furthermore, this makes it possible to ascertain a correction rule for correcting the transformation rule ascertained on the basis of the image representation of the first and second edge.

For example, at least three markers are created on the blank with the aid of the second examination apparatus.

According to a further embodiment, the plurality of markers are created by particle beam-induced deposition and/or etching and/or by embossing on the blank.

For example, the second examination apparatus comprises a device for particle beam-induced processing (e.g. deposition and/or etching) of the blank. For example, the device for particle beam-induced processing comprises a particle beam providing unit for providing a particle beam (e.g. electron beam, ion beam). Moreover, the device for particle beam-induced processing for example comprises a gas providing unit for providing a process gas (e.g. deposition gas, etching gas).

For example, the process gas is a deposition gas and/or an etching gas. For example, the process gas can be a mixture of a plurality of gaseous components, i.e. a process gas mixture. For example, the process gas can be a mixture of a plurality of gaseous components, of which each has only a certain molecule type.

In particular, alkyl compounds of main group elements, metals or transition elements are considered as deposition gases suitable for the deposition or for growing of elevated structures. Examples thereof include cyclopentadienyl(trimethyl) platinum (CpPtMe₃Me=CH₄), methylcyclopentadienyl(trimethyl)platinum (MeCpPtMe₃), tetramethyltin (SnMed), trimethylgallium (GaMe₃), ferrocene (Cp₂Fe), bisarylchromium (Ar₂Cr), and/or carbonyl compounds of main group elements, metals or transition elements, such as for example chromium hexacarbonyl(Cr(CO)₆), molybdenum hexacarbonyl (Mo(CO)₆), tungsten hexacarbonyl (W(CO)₆), dicobalt octacarbonyl (Co₂(CO)₈), triruthenium dodecacarbonyl (Ru₃(CO)₁₂), iron pentacarbonyl (Fe(CO)₅), and/or alkoxide compounds of main group elements, metals or transition elements, such as for example tetraethoxysilane (Si(OC₂H₅)₄), tetraisopropoxytitanium (Ti(OC₃H₇)₄), and/or halide compounds of main group elements, metals or transition elements, such as for example tungsten hexafluoride (WF₆), tungsten hexachloride (WCl₆), titanium tetrachloride (TiCl₄), boron trifluoride (BCl₃), silicon tetrachloride (SiCl₄), and/or complexes with main group elements, metals or transition elements, such as for example copper bis(hexafluoroacetylacetonate) (Cu(C₅F₆HO₂)₂), dimethylgold trifluoroacetylacetonate (Me₂Au(C₅F₃H₄O₂)), and/or organic compounds such as carbon monoxide (CO), carbon dioxide (CO₂), aliphatic and/or aromatic hydrocarbons, and more of the same.

A deposition gas can also comprise styrol, hexacarbonyl, ethylene, styrene, pyrene, cetane, formic acid, acrylic acid, propionic acid and/or methylmethacrylate.

For example, the etching gas can comprise: xenon difluoride (XeF₂), xenon dichloride (XeCl₂), xenon tetrachloride (XeCl₄), steam (H₂O), heavy water (D₂O), oxygen (O₂), ozone (O₃), ammonia (NH₃), nitrosyl chloride (NOCl) and/or one of the following halide compounds: XNO, XONO₂, X₂O, XO₂, X₂O₂, X₂O₄, X₂O₆, where X is a halide. Further etching gases for etching one or more of the deposited test structures are specified in the applicant's U.S. patent application Ser. No. 13/103,281, issued as U.S. Pat. No. 9,721,754 on Aug. 1, 2017, the entire content of which is incorporated by reference.

The process gas can comprise further additional gases, for example oxidizing gases such as hydrogen peroxide (H₂O₂), nitrous oxide (N₂O), nitrogen oxide (NO), nitrogen dioxide (NO₂), nitric acid (HNO₃) and other oxygen-containing gases, and/or halides such as chlorine (Cl₂), hydrogen chloride (HCl), hydrogen fluoride (HF), iodine (I₂), hydrogen iodide (HI), bromine (Br₂), hydrogen bromide (HBr), phosphorus trichloride (PCl₃), phosphorus pentachloride (PCl₅), phosphorus trifluoride (PF₃) and other halogen-containing gases, and/or reducing gases, such as hydrogen (H₂), ammonia (NH₃), methane (CH₄) and other hydrogen-containing gases. These additional gases can be used, for example, for etching processes, as buffer gases, as passivating media and the like.

According to a further embodiment, the plurality of markers have a circular form and/or a diameter of 10 nm or more, 50 nm or more, 100 nm or more and/or 300 nm or more.

If circular markers are used, the first examination apparatus can detect the markers more easily and ascertain their position better. In particular, a center of the markers can be ascertained more easily.

However, other shapes than circular can also be used for the markers.

A minimum size of 10 nm ensures that the first examination apparatus can detect the markers. Moreover, the larger the markers are, the better and the more reliably they can be detected by the first examination apparatus. For example, a maximum size of the markers is 50 μm.

According to a further embodiment, the plurality of markers are created in a regular pattern and/or regular grid or in an irregular pattern on the blank.

For example, the plurality of markers are created in a regular or irregular pattern/grid which completely covers a surface of the blank.

An example of a regular pattern is a regular grid with uniform distances between nodes of the grid.

An example of an irregular pattern is a distribution of the created markers on the surface of the blank, the density of which increases towards the edge of the blank.

According to a further embodiment, one or more defects of the blank are examined in the method, and a position of a defect arranged between the created markers is ascertained by interpolating the positions of the markers ascertained by the first examination apparatus.

As a result, locations of defects not lying on one of the created markers can also be transformed easily from the first to the second coordinate system.

For example, a position of a defect arranged between coordinates of the created markers is ascertained by interpolating the positions of the markers ascertained by the first examination apparatus.

For example, the interpolation comprises a triangulation, a Delauny triangulation, a radial basis function and/or any other interpolation method.

A reference blank comprising a plurality of markers at correspondingly predetermined nominal positions can also be provided in embodiments. The plurality of markers can have one or more of the aforementioned properties of the above-described markers. Then, the reference blank is arranged on the second stage of the second examination apparatus. Moreover, the positions of the plurality of markers of the reference blank are ascertained in the second coordinate system with the aid of the second examination apparatus. Furthermore, a correction rule serving to correct the transformation rule is ascertained on the basis of a deviation between the positions of the markers in the second coordinate system ascertained with the aid of the second examination apparatus and the nominal positions of the markers.

“A(n)” should not necessarily be understood as a restriction to exactly one element in the present case. Rather, a plurality of elements, such as for example two, three or more, can also be provided. Nor should any other numeral used here be understood to the effect that there is a restriction to exactly the stated number of elements. Rather, unless indicated otherwise, numerical deviations upwards and downwards are possible.

Further possible implementations of the invention also encompass not explicitly mentioned combinations of features or embodiments that are described above or hereinafter with respect to the exemplary embodiments. In this case, a person skilled in the art will also add individual aspects as improvements or supplementations to the respective basic form of the invention.

Further advantageous configurations and aspects of the invention are the subject matter of the dependent claims and also of the exemplary embodiments of the invention that are described below. The invention is explained in detail hereinafter on the basis of preferred embodiments with reference to the accompanying figures.

### BRIEF DESCRIPTION OF DRAWINGS

FIG. 1 shows a blank of a microlithographic photomask arranged in a first examination apparatus according to one embodiment;

FIG. 2 shows the blank from FIG. 1 arranged in a second examination apparatus according to one embodiment;

FIG. 3 shows images of the blank from FIG. 2 recorded by the second examination apparatus, wherein a first, second and third reference point on edges of the blank are captured in the images;

FIG. 4 illustrates the blank from FIG. 2 together with a first coordinate system of the first examination apparatus and a second coordinate system of the second examination apparatus;

FIG. 5 shows an enlarged detail from FIG. 4;

FIG. 6 shows a view similar to FIG. 4, wherein a translation of the first coordinate system relative to the second coordinate system is labelled;

FIG. 7 shows a view similar to FIG. 4, wherein a blank with rounded-off corners is illustrated;

FIG. 8 shows an image of a defect of the blank recorded by the second examination apparatus;

FIG. 9 shows a further embodiment of the second examination apparatus;

FIG. 10 illustrates a creation of markers on a blank using the second examination apparatus;

FIG. 11 shows a flowchart of a method for examining a blank of a microlithographic photomask according to one embodiment; and

FIG. 12 shows a flowchart of a method for examining a blank of a microlithographic photomask according to a further embodiment.

### DETAILED DESCRIPTION

Unless indicated otherwise, elements that are identical or functionally identical have been provided with the same reference signs in the figures. It should also be noted that the illustrations in the figures are not necessarily true to scale.

A method for examining a blank 100 for a microlithographic photomask according to one embodiment is described below.

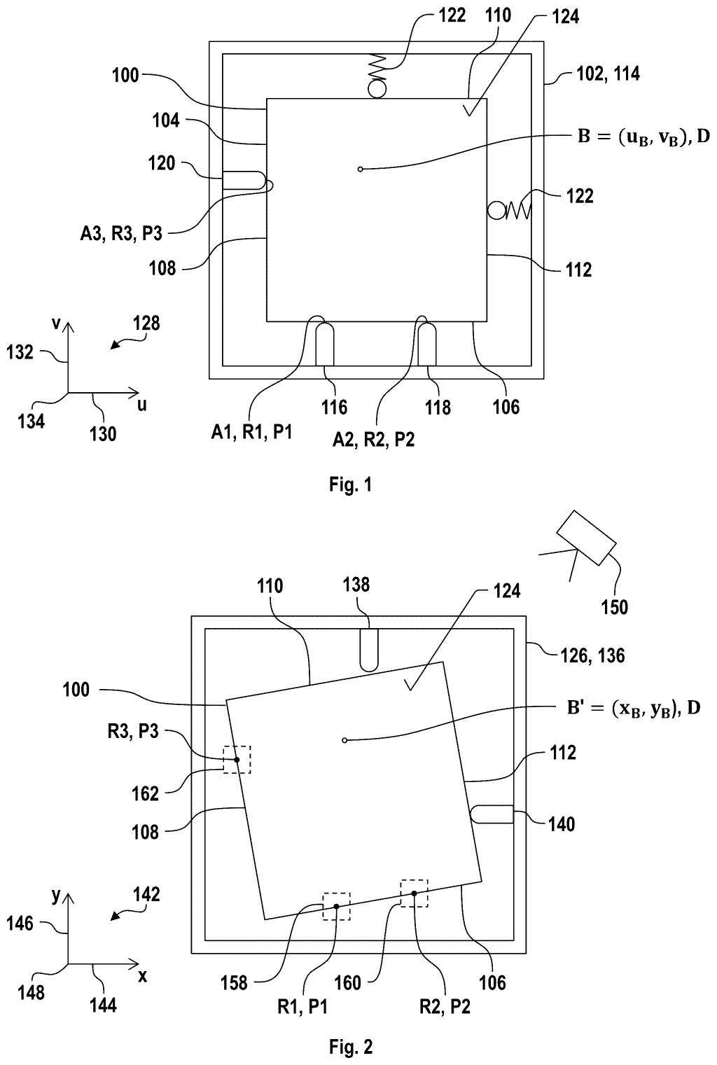

In a first step S1 of the method, a blank 100 for a microlithographic photomask is arranged in a first examination apparatus 102, as shown in FIG. 1. The blank 100 has a main extension plane 104 (uv-plane in FIG. 1). The blank 100 moreover comprises a first edge 106, a second edge 108, a third edge 110 and a fourth edge 112. In particular, the edges 106, 108, 110, 112 of the blank 100 are arranged parallel to its main extension plane 104. The first and second edge 106 and 108 are at an angle to one another, in particular arranged substantially perpendicular to one another. The third edge 110 is arranged opposite the first edge 106. Moreover, the fourth edge 112 is arranged opposite the second edge 108.

In particular, the first examination apparatus 102 comprises a first stage 114 for mounting the blank 100. The first stage 114 comprises a plurality of stops 116, 118, 120, against which the blank 100 rests. In particular, the blank 100 is arranged on the first stage 114 in the first step S1, in such a way that the first and the second edge 106, 108 rest against the stops 116, 118, 120 of the first stage 114.

In the example shown in FIG. 1, the first stage 114 comprises a first stop 116, a second stop 118 and a third stop 120. Furthermore, the blank 100 is arranged on the first stage 114 in such a way in this example that the first edge 106 of the blank 100 rests against the first and second stop 116, 118. Moreover, the second edge 108 of the blank 100 rests against the third stop 120.

The contact location A1, where the first edge 106 rests against the first stop 116, defines a first reference point R1 of the blank 100. Similarly, the contact location A2, where the first edge 106 rests against the second stop 118, defines a second reference point R2 of the blank 100. Furthermore, the contact location A3, where the second edge 108 rests against the third stop 120, defined a third reference point R3 of the blank 100.

In the example shown in FIG. 1, the first stage 114 also comprises elastic elements 122 under tension, which press the blank 100 in the direction of the stops 116, 118, 120. A first elastic element 122 is shown by way of example; it presses against the third edge 110 of the blank 100. Furthermore, a second elastic element 122 is shown by way of example; it presses against the fourth edge 112 of the blank 100. Instead of two elastic elements 122, more or fewer elastic elements can also be used.

In a second step S2 of the method, an examination location B on the blank 100 is ascertained with the aid of the first examination apparatus 102. For example, the examination location B is a location on a surface 124 of the blank 100. The examination location B of the blank 100 is a location that is initially examined by use of the first examination apparatus 102 and subsequently examined by means of a second examination apparatus 126 (FIG. 2).

The first examination apparatus 102 has a first coordinate system 128. As evident from FIG. 1, a first abscissa axis 130 of the first coordinate system 128 is labelled using reference sign u. A first ordinate axis 132 of the first coordinate system 128 is labelled using reference sign v. Reference sign 134 labels a first coordinate origin of the first coordinate system 128.

In step S2, the examination location B on the blank 100 is ascertained in the first coordinate system 128 with the aid of the first examination apparatus 102. In the process, a u-coordinate u_{B} and a v-coordinate v_{B}, for example, of the examination location B are ascertained in the first coordinate system 128.

For example, the method serves to examine one or more defects D of the blank 100. For example, the defects D can be particles, for instance foreign bodies and/or dust particles. In this case, a location B of one or more defects D of the blank 100 is ascertained in the first coordinate system 128 in step S2.

The blank 100 can be output from the first examination apparatus 102 at the end of step S2.

In a third step S3 of the method, the blank 100 is arranged in the second examination apparatus 126, as illustrated in FIG. 2.

The second examination apparatus 126 comprises a second stage 136 for mounting the blank 100. The second stage 136 can also comprise one or more stops 138, 140. In the example shown in FIG. 2, the second stage 136 comprises a stop 138 which rests against the third edge 110 of the blank 100. Moreover, the second stage 136 comprises a further stop 140 by way of example; it rests against the fourth edge 112 of the blank 100. The second stage 136 can also comprise more or fewer stops than the two 138, 140 shown. This also includes the case in which the second stage 136 does not comprise any stop. Moreover, stops 138, 140 of the second stage 136 can also rest against different edges to the third and fourth edge 110, 112 of the blank 100.

The second examination apparatus 126 has a second coordinate system 142. The second coordinate system 142 has a second abscissa axis 144 labelled by reference sign x, a second ordinate axis 146 labelled by reference sign y and a coordinate origin 148.

As illustrated in FIG. 2, the blank 100 is arranged in the second stage 136 of the second examination apparatus 126 in a manner twisted and displaced relative to the second stage 136 and the second coordinate system 142. For example, such twists and/or displacements arise due to defects on account of tolerances in the mechanical construction. For example, the aforementioned displacements have an extent of a few micrometers (μm) to a few millimeters (mm). Furthermore, the aforementioned twists for example have an extent of a few microradians (μrad) to a few milliradians (mrad). Attention is drawn to the fact that this twist and displacement has been depicted in exaggerated fashion for illustrative purposes in FIG. 2 and the subsequent figures.

The coordinates u_{B} and v_{B} of the examination location B in the first coordinate system 128 were ascertained by use of the first examination apparatus 102. This examination location B=(u_{B}, v_{B}) ascertained by use of the first examination apparatus 102 should now be found in the second coordinate system 142 of the second examination apparatus 126. In relation to the second coordinate system 142 of the second examination apparatus 126, the examination location B now appears at the coordinates x_{B} and y_{B} of the second coordinate system 142, as illustrated in FIG. 2.

For a clear illustration, the examination location B=(u_{B}, v_{B}) found in the first coordinate system 128 by use of the first examination apparatus 102 is labelled by reference sign B. Moreover, the examination location B′=(x_{B}, y_{B}) found in the second coordinate system 142 by use of the second examination apparatus 126 is labelled by reference sign B′, even though this is the same location merely in a different coordinate.

In order to find and be able to examine the examination location B, B′ by use of the second examination apparatus 126, it is necessary to convert the location B=(u_{B}, v_{B}) ascertained by the first examination apparatus 102 into the second coordinate system 142 of the second examination apparatus 126.

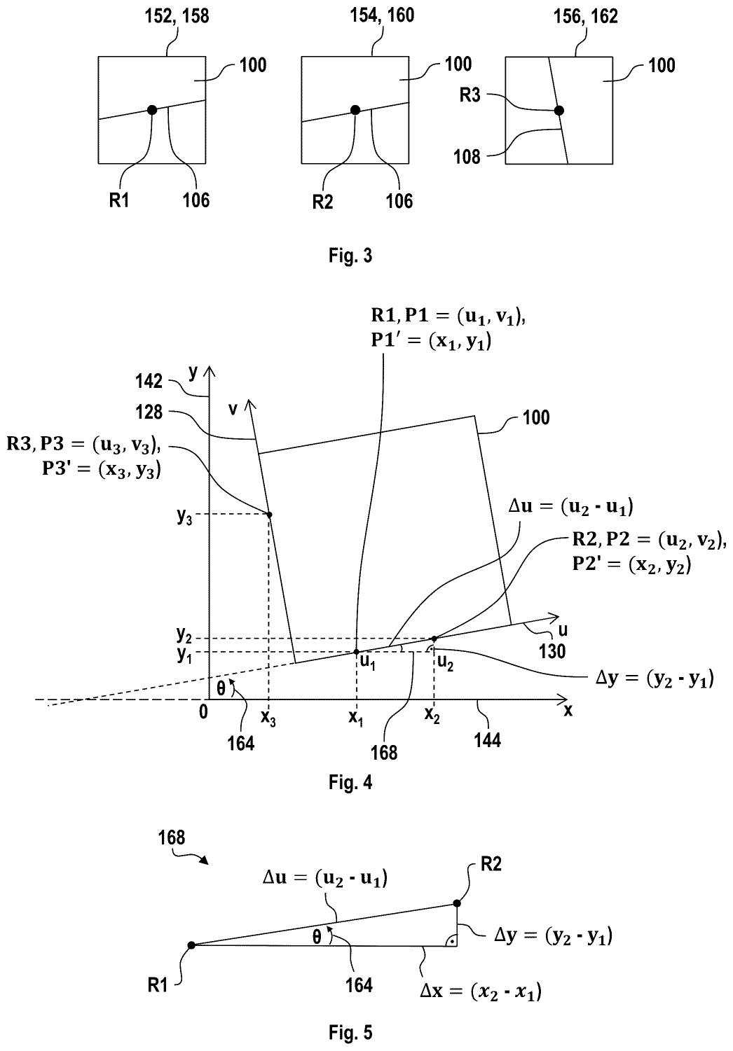

In a fourth step S4 of the method, at least one image 152, 154, 156 (FIG. 3) of the blank 100 is recorded using an image recording unit 150 of the second examination apparatus 126. The image recording unit 150 is only sketched in FIG. 2. In particular, the image recording unit 150 is a high-resolution image recording unit with a spatial resolution of for example 50 μm or better, for example also a spatial resolution of a few nanometers. For example, the image recording unit 150 is a scanning microscope, for example a scanning electron microscope as described in detail in the context of FIG. 9.

In particular, the at least one image 152, 154, 156 of the blank 100 is recorded using the image recording unit 150, in such a way that the first and second edge 106, 108 of the blank 100 are captured at least in part in the at least one image 152, 154, 156.

By preference, a separate image 152, 154, 156 (first to third image 152 to 156) is recorded for each reference point R1, R2, R3 of the blank 100, the image capturing the corresponding reference point R1, R2, R3 at the corresponding edge 106, 108 and a portion of the corresponding edge 106, 108, as evident from FIG. 3. The exemplary image details 158, 160, 162 of the images 152, 154, 156 are labelled in FIG. 2.

A transformation rule is ascertained in a fifth step S5 of the method. The transformation rule serves to transform the examination location B captured in the first coordinate system 128 into an examination location B′ in the second coordinate system 142 of the second examination apparatus 126. The transformation rule is ascertained on the basis of the first and second edge 106, 108 captured in the at least one image 152, 154, 156.

In particular, a position P1, P2, P3 of the first and the second edge 106, 108 in the first coordinate system 128 and a position P1′, P2′, P3′ of the first and the second edge 106, 108 in the second coordinate system 142 are ascertained on the basis of image processing for the at least one image 152, 154, 156. For example, a position P1, P2, P3 of the first and second edge 106, 108 is ascertained at the three reference points R1, R2, R3 in the first coordinate system 128 on the basis of image processing for the at least one image 152, 154, 156. For example, a position P1′, P2′, P3′ of the first and second edge 106, 108 is moreover ascertained at the three reference points R1, R2, R3 in the second coordinate system 142 on the basis of image processing for the at least one image 152, 154, 156.

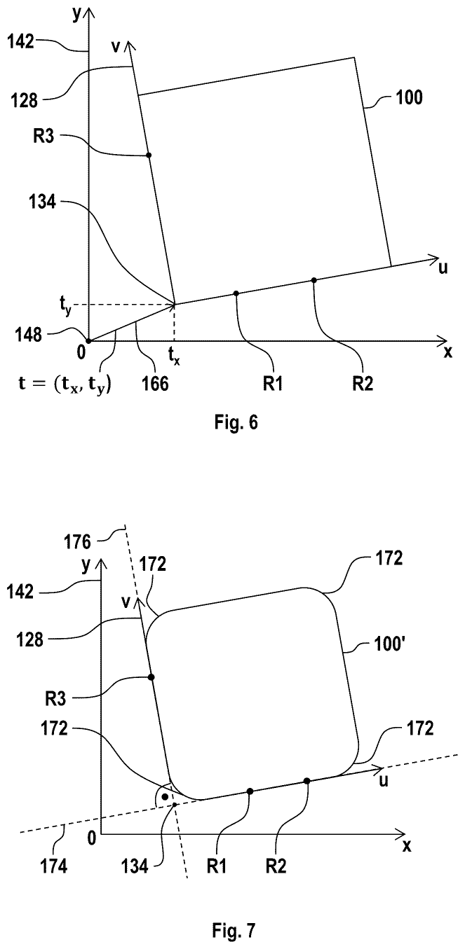

FIGS. 4 and 5 label a rotation 164 of the first coordinate system 128 through a rotation angle Θ relative to the second coordinate system 142. Moreover, FIG. 6 labels a translation 166 of the first coordinate system 128 according to a translation vector ť relative to the second coordinate system 142.

For the illustration in FIGS. 4 and 6 and the ascertainment of the transformation rule, the assumption is made that a coordinate system of the blank 100 corresponds to the first coordinate system 128 of the first examination apparatus 102. In other words, a possible deviation in relation to the first coordinate system 128 of the first examination apparatus 102 is disregarded when the blank 100 is arranged in step S1.

As illustrated in FIG. 4, the first reference point R1 has a position P1=(u₁, v₁) in the first coordinate system 128 and a position P1′=(x₁, y₁) in the second coordinate system 142. Furthermore, the second reference point R2 has a position P2=(u₂, v₂) in the first coordinate system 128 and a position P2′=(x₂, y₂) in the second coordinate system 142. Moreover, the third reference point R3 has a position P3=(u₃, v₃) in the first coordinate system 128 and a position P3′=(x₃, y₃) in the second coordinate system 142.

In step S5, a respective ordinate position y₁, y₂ in the second coordinate system 142 is ascertained, for example for the first and second reference point R1, R2, on the basis of an image analysis of the image 154 (FIG. 3). Moreover, an abscissa position x₃ in the second coordinate system 142 is ascertained, for example for the third reference point R3, on the basis of the image analysis.

In the example of FIGS. 4 to 6, the first coordinate system 128 of the first examination apparatus 102 is twisted through the rotation angle Θ relative to the second coordinate system 142 of the second examination apparatus 126. That is to say the first abscissa axis 130 of the first coordinate system 128 is rotated through the rotation angle Θ relative to the second abscissa axis 144 of the second coordinate system 142.

Then, the rotation angle Θ can be calculated from a right-angled slope triangle 168 formed on the basis of the first and second abscissa axis 130, 144. In particular, a length Δy of the opposite side of this right-angled triangle 168 can be calculated from the ascertained ordinate positions y₁, y₂ of the first and second reference point R1, R2 in the second coordinate system 142 as Δy=y₂−y₁.

Furthermore, the length Δx of the adjacent side of this right-angled triangle 168 can be assumed approximately to be of the same magnitude as a length Δu of the hypotenuse of this right-angled triangle 168. In particular, the length Δu is the distance between the first and second reference point R1, R2 in the first coordinate system. For example, the length Δu is ascertained on the basis of construction data of the first examination apparatus 102 ascertained in advance, in particular on the basis of a distance, ascertained in advance, between the first and second stop 116, 118 of the first stage 114 of the first examination apparatus 102.

The rotation angle Θ then arises approximately from the arctangent of the quotient of opposite side Δy and adjacent side Δx, according to the following equation:

$$tan Θ = \frac{Δ y}{Δ x} .$$

In the example shown in FIGS. 4 and 6, the first coordinate system 128 of the first examination apparatus 102 is displaced relative to the second coordinate system 142 of the second examination apparatus 126 according to the translation vector \vec{t} (FIG. 6). That is to say, the first coordinate origin 134 of the first coordinate system 128 is displaced relative to the second coordinate origin 148 of the second coordinate system 142 by the translation vector \vec{t}=(tₓ, t_{y}), as shown in FIG. 6.

For example, the transformation rule comprises a transformation matrix T (e.g. affine transformation matrix) according to the following equation:

$$( \begin{matrix}x \\ y \\ 1\end{matrix} ) = T ( \begin{matrix}u \\ v \\ 1\end{matrix} ) = ( \begin{matrix}cos Θ & - sin Θ & {t}_{x} \\ sin Θ & cos Θ & {t}_{y} \\ 0 & 0 & 1\end{matrix} ) ( \begin{matrix}u \\ v \\ 1\end{matrix} ) .$$

In the equation above, u and v denote coordinates of a location (e.g. examination location B) in the first coordinate system 128, x and y denote coordinates of a location (e.g. examination location B′) in the second coordinate system 142, 0 denotes the rotation angle of the rotation of the first coordinate system 128 relative to the second coordinate system 142 and tₓ and t_{y} denote the vector components of the translation vector \vec{t}.

As presented above, the rotation angle Θ can be calculated from Δx and Δy.

The vector components tₓ and t_{y} of the translation vector \vec{t} can be ascertained on the basis of the ascertained position P3 (in particular x₃) of the third reference point R3 in the second coordinate system 142 and the ascertained position P1, P2 (in particular y₁, y₂) of the first or second reference point R1, R2 in the second coordinate system 142.

In particular, the above transformation rule can be rewritten as follows by way of matrix multiplication:

$$x = u cos Θ - v sin Θ + {t}_{x}$$

$$y = u sin Θ + v cos Θ + {t}_{y} .$$

Thus, the following arises for the reference point R2:

$${y}_{2} = {u}_{2} sin Θ - {v}_{2} cos Θ + {t}_{y} .$$

Thus, the following arises for the reference point R3:

$${x}_{3} = {u}_{3} cos Θ - {v}_{3} sin Θ + {t}_{x} .$$

These two equations can be solved for tₓ and t_{y}, respectively. Since the position y₂ of the reference point R2 and the position x₃ of the reference point R3 were ascertained by use of image processing from the recorded images 154, 156 (see also FIG. 4) and since u₁ and u₂ are known from the construction data of the first examination apparatus 102, tₓ and t_{y} can be ascertained from the equations solved for tₓ and t_{y}, respectively.

With the ascertained rotation angle Θ and the ascertained vector components tₓ and t_{y} of the translation vector \vec{t}, all matrix elements of the transformation matrix T are known. Hence, any location B (e.g. one or more examination locations B) in the first coordinate system 128 can be transformed into a corresponding location B′ in the second coordinate system 142.

If the method is for example used to examine one or more defects D on the blank 100, then the first examination apparatus 102 can ascertain locations B=(u_{B}, v_{B}) in the first coordinate system. The first examination apparatus 102 can furthermore transmit the ascertained locations B=(u_{B}, v_{B}) to the second examination apparatus 126. A computing device (not shown in FIG. 2; e.g. control device 242 in FIG. 9) of the second examination apparatus 126 can thereupon convert the transmitted locations B=(u_{B}, v_{B}) into corresponding locations B′=(x_{B}, y_{B}) in the second coordinate system 142 of the second examination apparatus 126 by applying the transformation rule with the transformation matrix T. Hence, defects D of the blank 100 can be easily found by the second examination apparatus 126 and can be examined in detail—e.g. with a high spatial resolution.

For example, should the intention be to examine a plurality of defects D or a plurality of locations B, B′ on the blank 100, it can be sufficient to ascertain the transformation rule with the transformation matrix T only once. This is the case, in particular, if the blank 100 is not moved in the second examination apparatus 126. Then, a plurality of locations B=(u_{B}, v_{B}) transmitted by the first examination apparatus 102 can be converted into a corresponding plurality of locations B′=(x_{B}, y_{B}) in the second coordinate system 142 of the second examination apparatus 126 by applying the one transformation rule.

FIG. 7 illustrates a case in which a blank 100′ for a lithography mask has rounded-off corners 172.

The assumption is made in the present case—as mentioned above—that a coordinate system of the blank 100′ corresponds to the first coordinate system 128. In the case of rounded-off corners 172 of the blank 100′ or else in the case of chamfered corners (not shown) of the blank 100′, the coordinate origin 134 of the first coordinate system 128 can be ascertained on the basis of the conditions set forth below. As evident from FIG. 7, it firstly holds true that the coordinate origin 134 of the first coordinate system 128 is located on a first straight line 174 on which the first and the second reference point R1, R2 are also located. Secondly, a second straight line 176 is defined by the coordinate origin 134 of the first coordinate system 128 and the third reference point R3. It holds true that the first straight line 174 is arranged perpendicular to the second straight line 176. Hence, the coordinate origin 134 of the first coordinate system 128 can be ascertained even in the event of rounded-off corners 172 and/or chamfered corners of the blank 100′.

Optionally, steps S1 to S5 can be carried out repeatedly to allow ascertainment of an averaged transformation rule (statistical mean) with greater accuracy.

Optionally, steps S1 to S5 can also be carried out repeatedly in such a way that they are carried out for a plurality of different first examination apparatuses 102. For example, the plurality of different first examination apparatuses 102 differ from one another in that the stops 116 to 120 rest against the blank 100 at different contact locations A1 to A3. By carrying out steps S1 to S5 at least once for each of the plurality of different first examination apparatuses 102, a plurality of different transformation rules are ascertained in step S5. This ascertained plurality of different transformation rules is subsequently averaged. The application of the averaged transformation rule created thus allows the latter to be applied to any desired first examination apparatus 102 for coordinate transformation purposes.

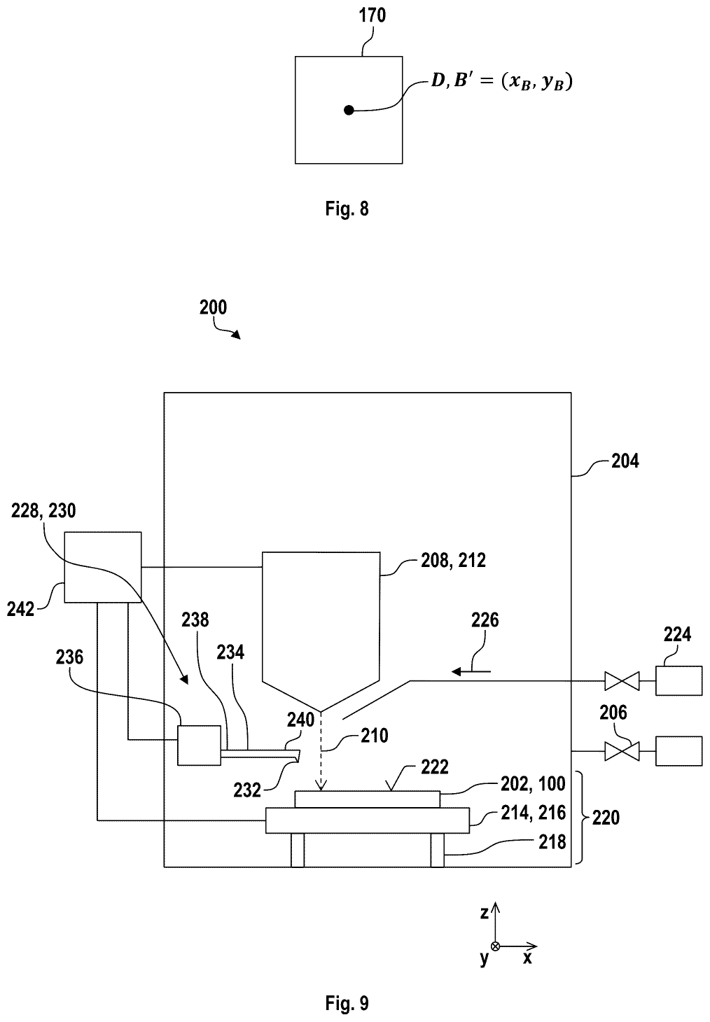

In an optional sixth step S6 of the method, at least one image 170 (FIG. 8) of the at least one defect D is recorded using the second examination apparatus 126. In this case, the image recording unit 150 is aligned on the basis of the location B′=(x_{B}, y_{B}) transformed into the second coordinate system 142. In particular, the image recording unit 150 is controlled such that the location B′=(x_{B}, y_{B}) transformed into the second coordinate system 142 is captured in the image 170. For example, the image recording unit 150 is controlled such that the location B′=(x_{B}, y_{B}) transformed into the second coordinate system 142 is imaged in a center of the image 170.

In an optional further step of the method, the defect D is removed from the blank 100 by use of the second examination apparatus 126.

FIG. 9 shows a further exemplary embodiment of the second examination apparatus 200, which can be used in the methods described above and/or below. The second examination apparatus 200 in FIG. 9 is an apparatus for examining (i.e. analyzing) a sample 202, for example the blank 100 (FIG. 1). The second examination apparatus 200 can also be additionally configured as an apparatus for processing the sample 202, for example the blank 100.

For example, the apparatus 200 comprises a housing 204. The housing 204 can be evacuated, for example by use of a vacuum pump 206 (e.g. to a residual gas pressure of 10⁻⁵-10⁻⁹ mbar).

The apparatus 200 also comprises a particle beam providing unit 208 which is arranged in the housing 204 and serves to provide a particle beam 210. For example, the particle beam providing unit 208 is embodied as an electron column 212 for providing an electron beam 210.

The particle beam providing unit 208, e.g. the electron column 212, can be designed in particular as an electron microscope 212 (scanning electron microscope). The scanning electron microscope 212 is an example of the image recording unit 150 (FIG. 2).

The apparatus 200 (as an example of the second examination apparatus) for example comprises a sample stage 214 (as an example for the second stage) for mounting the sample 202 (e.g. the blank 100). The sample stage 214 can furthermore comprise a positioning unit 216 (not illustrated individually), by means of which the sample stage 214 is displaceable relative to a base 218 in the three spatial directions x, y and z, for example, and is rotatable about at least one axis (e.g. an axis arranged parallel to the z-direction in FIG. 9), for example. Reference sign 220 denotes a sample stage device which comprises the sample stage 214, the base 218 and the positioning unit 216.

The apparatus 200 may optionally also comprise a process gas providing unit 224 for providing process gas 226. The process gas providing unit 224 can be used together with the particle beam providing unit 208 in order to carry out particle beam-induced processing processes on the sample 202 (e.g. the blank 100). For this purpose, for example, a process gas 226 is supplied by use of the process gas providing unit 224 and is irradiated by the particle beam 210.

The apparatus 200 can optionally also comprise a manipulator unit 228 (e.g. micromanipulator unit and/or nanomanipulator unit) for carrying out manipulations on the sample 202 or on a surface 222 of the sample 202 (e.g. on a surface 124 of the blank 100, FIG. 2).

By way of example, the manipulator unit 228 comprises an atomic force microscope 230. The atomic force microscope 230 comprises a tip 232 for analyzing and/or processing the sample 202. The tip 232 is arranged on a cantilever 234 secured movably to a positioning unit 236 (movement unit). In particular, the cantilever 234 comprises a first end 238 (base end 238), at which the cantilever 234 is movably secured to the positioning unit 236. Furthermore, the cantilever 234 comprises a second end 240 (free end 240), at which the tip 232 is arranged. With the aid of the positioning unit 236, the tip 232 can be moved in three spatial directions x, y, z (translational movement in x-, y- and z-direction). Movements in the x- and/or y-direction are referred to as lateral movements herein. Herein, movements in the z-direction are referred to as an approach of the sample 202 by the tip 232 (negative z-direction) and a removal/away movement of the tip 232 from the sample 202 (positive z-direction).

The atomic force microscope 230 can be used to perform manipulations on the sample 202. For example, the tip 232 can be used to pick up (i.e. lift) a particle D (FIGS. 1, 2) adhering to a sample surface 222 of the sample 202. For this purpose, the tip 232 is correspondingly moved for example by use of the positioning unit 236. For assistance, the sample stage 120 can also be displaced by use of its positioning unit 216. The picking-up (i.e. lifting) of the particle D by the tip 232 for example can be monitored live with the electron microscope 212. Afterwards, the tip 232 is for example moved by use of the positioning unit 236 to a repository unit (not shown), where the particle D is transferred from the tip 232 to the repository unit.

The atomic force microscope 230 can also be configured to record images—in addition or in an alternative to the manipulation.

The apparatus 200 moreover comprises, for example, a control device 242 for controlling the manipulator unit 228 (e.g. the positioning unit 236), the sample stage 214 or the further positioning unit 216, the particle beam providing unit 208 and/or the process gas providing unit 224.

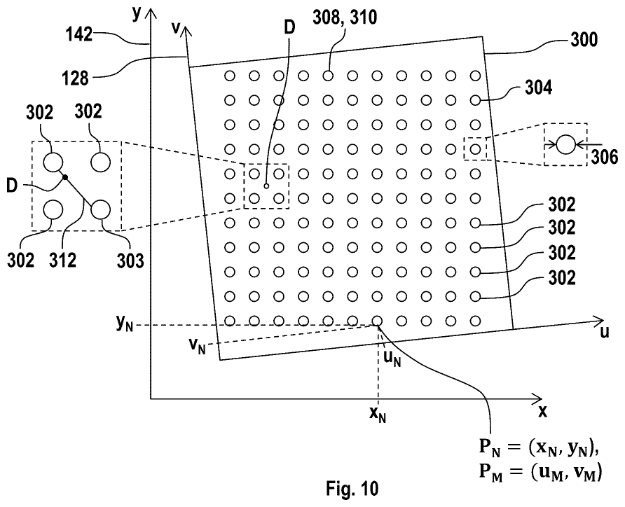

A method for examining a blank 300 of a microlithographic photomask according to a further embodiment is described below with reference to FIGS. 10 and 12.

In a first step S101 of the method according to the further embodiment (FIG. 12), the blank 300 is arranged on the second stage 136 of the second examination apparatus 126 (FIG. 2).

In a second step S102 of the method according to the further embodiment, a plurality of markers 302 are created on the blank 300 with the aid of the second examination apparatus 126. In FIG. 10, some of the markers 302 have been provided with a reference sign by way of example.

For example, the plurality of markers 302 are created by particle beam-induced deposition and/or etching. For example, the embodiment of the second examination apparatus shown in FIG. 9 can be used to this end.

For example, a process gas 226 is provided on a surface of the blank 300 (e.g. on the surface 222 of the sample 202 in FIG. 9) by use of the gas providing unit 224. Furthermore, the particle beam providing unit 208 (e.g. the electron column 212) provides an activating particle beam 210 (e.g. electron beam) on the surface of the blank 300. This can cause a chemical reaction which leads to the deposition of material from the gas phase of the process gas 226 (in the case of a deposition gas) on the surface of the blank 300 or to the etching away of material from the blank (in the case of an etching gas).

In an alternative, the markers 302 can also be created on a surface of the blank 300 by embossing.

By preference, the plurality of markers 302 each have a circular form 304, as evident in FIG. 10. As a result, the position of the markers 302, in particular a center of the markers 302, can be ascertained more easily in the subsequent step S2′ by the first examination apparatus 102.

Furthermore, the plurality of markers 302 for example each have a diameter 306 of at least 10 nm or larger. The larger the diameter 306 of the individual markers 302, the easier they are to detect by the first examination apparatus 102 in the subsequent step S2′.

In the example of FIG. 10, the plurality of markers 302 are arranged in a regular pattern 308, in particular in a regular grid 310. In particular, the markers 302 are arranged on nodes of the regular grid 310. Furthermore, the nodes are arranged at regular distances from one another.

Even though this is not shown in the figures, the markers 302 can also be created in an irregular pattern on the blank 300.

The example of FIG. 10 shows a multiplicity of created markers 302. However, in other examples, more or fewer than the number of markers 302 shown in FIG. 10 can also be created on the blank 300 with the aid of the second examination apparatus 126. For example, it is also possible that only three markers 302 are created on the blank 300.

The plurality of markers 302 are created on the blank 300 in step S102 according to predetermined nominal positions P_{N} as per the second coordinate system 142. By way of example, the nominal position P_{N}=(x_{N}, y_{N}) in the second coordinate system 142 is labelled for one of the markers 302 shown in FIG. 10.

It can be the case that the blank 300 is arranged with a slight twist and/or displacement in the second stage 136 of the second examination apparatus 126—as is the case in FIG. 2 as well. Then, as shown in FIG. 10, the markers 302 are created on the blank 300 in accordance with the inaccurate arrangement of the blank 300 in the stage 136. Hence, the markers 302 created contain information as regards the inaccurate arrangement of the blank 300 in the stage 136 of the second examination apparatus 126.

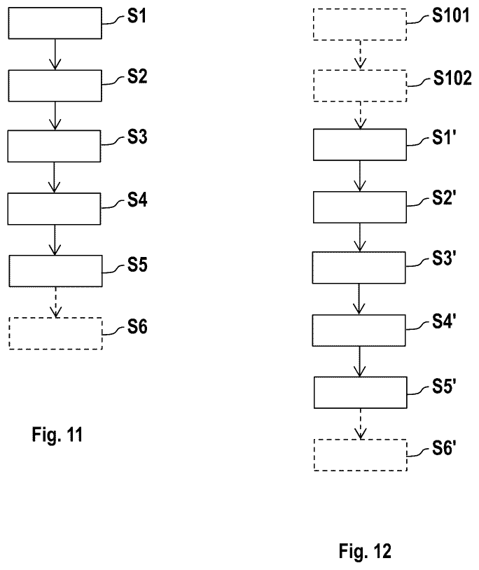

Following step S102, steps S1′ to S5′ (FIG. 12)—corresponding to steps S1 to S5 of the above-described method (FIG. 11)—are carried out.

In this case, locations P_{M} of the plurality of created markers 302 in the first coordinate system 128 are ascertained in step S2′ with the aid of the first examination apparatus 102. Furthermore, a deviation is ascertained between the positions P_{M} of the markers 302 in the first coordinate system 126 ascertained with the aid of the first examination apparatus 102 and the nominal positions P_{N} of the markers 302 in the second coordinate system 142.

Subsequently, steps S3′ and S4′ are carried out analogously to steps S3 and S4.

Then step S5′ is carried out, wherein, following the ascertainment of the transformation rule, the markers 302 detected by the first examination apparatus 102 in S2′ are used to further improve the ascertained transformation rule. In particular, the deviation of the positions P_{M} of the markers 302 in the first coordinate system 126 from the nominal positions P_{N} of the markers 302 in the second coordinate system 142, ascertained in step S2′, is used to ascertain a correction rule for correcting the transformation rule.

In particular, the method can be applied in such a way that the markers 302 are applied to a (e.g. single) blank to be examined, and hence the deviations are ascertained once. The deviation ascertained thus can then be applied when examining a different blank, it being possible in particular to carry out corresponding corrections.

A situation that can arise should the method be used to examine one or more defects D of the blank 300 is that a defect D is arranged at a coordinate of one of the markers 302. A position of the defect D can then be ascertained easily. However, if a position of a defect D is arranged between coordinates of the created markers 302, then it is possible to apply an interpolation 312 between the positions P_{M} of the markers 302 ascertained by the first examination apparatus 102; this is illustrated in FIG. 10.

In some implementations, the operations associated with processing of data described in this document can be performed by one or more programmable processors executing one or more computer programs to perform the functions described in this document. A computer program can be written in any form of programming language, including compiled or interpreted languages, and it can be deployed in any form, including as a stand-alone program or as a module, component, subroutine, or other unit suitable for use in a computing environment.

For example, the control device 242 (or a computing device of the first or second examination apparatus) can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of the control device 242 (or a computing device of the first or second examination apparatus) can include one or more processors for executing instructions and one or more storage area devices for storing instructions and data. Generally, the control device 242 (or a computing device of the first or second examination apparatus) will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, and flash storage devices; magnetic disks, e.g., internal hard disks or removable disks; magneto-optical disks; and CD-ROM, DVD-ROM, and/or Blu-ray discs.

In some implementations, the processes that involve processing of data can be implemented using software for execution on one or more mobile computing devices, one or more local computing devices, and/or one or more remote computing devices. For instance, the software forms procedures in one or more computer programs that execute on one or more programmed or programmable computer systems, either in the mobile computing devices, local computing devices, or remote computing systems (which may be of various architectures such as distributed, client/server, or grid), each including at least one processor, at least one data storage system (including volatile and non-volatile memory and/or storage elements), at least one wired or wireless input device or port, and at least one wired or wireless output device or port.

In some implementations, the software may be provided on a medium, such as a CD-ROM, DVD-ROM, Blu-ray disc, solid state drive, or hard disk drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Although the present invention has been described on the basis of exemplary embodiments, it is modifiable in diverse ways.

Furthermore, although the present invention is defined in the attached claims, it should be understood that the present invention can also be defined in accordance with the following embodiments:

Embodiment 1. A method for examining a blank (100) of a microlithographic photomask, including the steps of:
a) arranging (S1) the blank (100) on a first stage (114) of a first examination apparatus (102) such that a first and a second edge (106, 108) of the blank (100) rest against stops (116, 118, 120) of the first stage (114),
b) ascertaining (S2) an examination location (B) on the blank (100) in a first coordinate system (128) with the aid of the first examination apparatus (102),
c) arranging (S3) the blank (100) on a second stage (136) of a second examination apparatus (126) having an image recording unit (150),
d) recording (S4) at least one image (152, 154, 156) of the blank (100) using the image recording unit (150) such that the first and second edge (106, 108) are captured at least in part, and
e) ascertaining (S5) a transformation rule on the basis of the first and second edge (106, 108) captured in the at least one image (152, 154, 156), in order to transform the examination location (B) captured in the first coordinate system (128) into a second coordinate system (142) of the second examination apparatus (126).

Embodiment 2. The method according to embodiment 1, wherein the second examination apparatus (126) comprises a scanning microscope apparatus (212), a scanning electron microscope apparatus (212), a scanning probe microscope apparatus and/or an atomic force microscope apparatus (230).

Embodiment 3. The method according to embodiment 1 or 2, wherein a spatial resolution of the image recording unit (150) of the second examination apparatus (126) is 100 μm or better, 50 μm or better, 30 μm or better, 10 μm or better, 5 μm or better, 1 μm or better, 0.1 μm or better, 50 nm or better, 10 nm or better, 5 nm or better and/or 3 nm or better.

Embodiment 4. The method according to any of embodiments 1 to 3, wherein
one or more defects (D) of the blank (100) are examined in the method,
a location (B) of at least one defect (D) of the blank (100) is ascertained in the first coordinate system (128) in step b) with the aid of the first examination apparatus (102), and
the ascertained transformation rule serves to transform the location (B) of the at least one defect (D) captured in the first coordinate system (128) into a location (B′) in the second coordinate system (142).

Embodiment 5. The method according to embodiment 4, including after step e):
recording (S6) at least one image (152, 154, 156) of the at least one defect (D) using the image recording unit (150) of the second examination apparatus (126), wherein the image recording unit (150) is aligned on the basis of the location (B′) of the at least one defect (D) which has been transformed into the second coordinate system (142).

Embodiment 6. The method according to any of embodiments 1 to 5, wherein
the first stage (114) comprises a first, second and third stop (116, 118, 120),
the blank (100) is arranged on the first stage (114) in such a way that the first edge (106) rests against the first and second stop (116, 118) and the second edge (108) rests against the third stop (120) such that a first, second and third reference point (R1, R2, R3) of the blank (100) are defined accordingly at contact locations (A1, A2, A3) of the first, second and third stops (116, 118, 120) on the first and second edge (106, 108),
an image (152, 154, 156) of the blank (100) is recorded in step d) for each reference point (R1, R2, R3), the corresponding reference point (R1, R2, R3) being captured in the image, and
the transformation rule is ascertained on the basis of the first, second and third reference points (R1, R2, R3) captured in the recorded images (152, 154, 156).

Embodiment 7. The method according to embodiment 6, wherein
positions (P1, P2) of the first and the second reference point (R1, R2) in the second coordinate system (142) are ascertained on the basis of image processing for the corresponding recorded images (152, 154), and/or
a position (P3) of the third reference point (R3) in the second coordinate system (142) is ascertained on the basis of image processing for the corresponding recorded image (156).

Embodiment 8. The method according to embodiment 7, wherein
the transformation rule includes a rotation (164) through a rotation angle (Θ) and/or a translation (166) with a translation vector (\vec{t}), and
the rotation angle (Θ) is ascertained on the basis of the ascertained position (P1, P2) of the first and second reference point (R1, R2) in the second coordinate system (128, 142), and/or
vector components (tₓ, t_{y}) of the translation vector (\vec{t}) are ascertained on the basis of the ascertained position (P3) of the third reference point (R3) in the second coordinate system (142) and the ascertained position (P1, P2) of the first or second reference point (R1, R2) in the second coordinate system (142).

Embodiment 9. The method according to embodiment 7 or 8, wherein the transformation rule includes a transformation matrix according to the following equation:

$$( \begin{matrix}x \\ y \\ 1\end{matrix} ) = ( \begin{matrix}cos Θ & - sin Θ & {t}_{x} \\ sin Θ & cos Θ & {t}_{y} \\ 0 & 0 & 1\end{matrix} ) ( \begin{matrix}u \\ v \\ 1\end{matrix} ) ,$$

where u and v denote coordinates of a location (B) in the first coordinate system (128), x and y denote coordinates of a location (B′) in the second coordinate system (142), Θ denotes a rotation angle of a rotation (164) of the first coordinate system (128) relative to the second coordinate system (142), and tₓ and t_{y} denote a translation (166) of the first coordinate system (128) relative to the second coordinate system (142), and/or
the transformation rule includes a rotation (164) through a rotation angle Θ, which satisfies the following equation:

$$tan Θ = \frac{Δ y}{Δ x} ,$$

where Θ denotes a rotation angle of a rotation (164) of the first coordinate system (128) relative to the second coordinate system (142), Δx denotes a difference in the abscissa coordinates (x₁, x₂) of the first and second reference point (R1, R2) in the second coordinate system (142), and Δy denotes a difference in the ordinate coordinates (y₁, y₂) of the first and second reference point (R1, R2) in the second coordinate system (142).

Embodiment 10. The method according to any of embodiments 6 to 9, wherein the ascertainment of the transformation rule includes an ascertainment of a coordinate origin (134) of the first coordinate system (128) on the basis of the conditions that
the coordinate origin (134) of the first coordinate system (128) is located on a first straight line (174) on which the first and the second reference point (R1, R2) are also located, and
the first straight line (174) is arranged perpendicular to a second straight line (176), on which the coordinate origin (134) of the first coordinate system (128) and the third reference point (R3) are located.

Embodiment 11. The method according to any of embodiments 1 to 10, wherein
the method includes prior to step a):
   arranging (S101) the blank (300) on the second stage (136) of the second examination apparatus (126), and
   using the second examination apparatus (126) to create (S102) a plurality of markers (302) on the blank (300) in accordance with predetermined nominal positions (P_{N}) as per the second coordinate system (142), ascertaining positions (P_{M}) of the plurality of markers (302) in the first coordinate system (128) in step b) with the aid of the first examination apparatus (102), and
   ascertaining a correction rule serving to correct the transformation rule in step e) on the basis of a deviation between the positions (P_{M}) of the markers (302) in the first coordinate system (128) ascertained with the aid of the first examination apparatus (102) and the nominal positions (P_{N}) of the markers (302) in the second coordinate system (142).

Embodiment 12. The method according to embodiment 11, wherein the plurality of markers (302) are created by particle beam-induced deposition and/or etching and/or by embossing on the blank (300).

Embodiment 13. The method according to embodiment 11 or 12, wherein the plurality of markers (302) have a circular form (304) and/or a diameter (306) of 10 nm or more, 50 nm or more, 100 nm or more and/or 300 nm or more.

Embodiment 14. The method according to any of embodiments 11 to 13, wherein the plurality of markers (302) are created in a regular pattern (308) and/or regular grid (310) or in an irregular pattern on the blank (300).

Embodiment 15. The method according to any of embodiments 11 to 14, wherein one or more defects (D) of the blank (300) are examined in the method, and a position (B) of a defect (D) arranged between the created markers (302) is ascertained by interpolating (312) the positions (P_{M}) of the markers (302) ascertained by the first examination apparatus (102).

### LIST OF REFERENCE SIGNS

100, 100′ Blank
102 Examination apparatus
104 Main extension plane
106 Edge
108 Edge
110 Edge
112 Edge
114 Stage
116 Stop
118 Stop
120 Stop
122 Elastic element
124 Surface
126 Examination apparatus
128 Coordinate system
130 Abscissa axis
132 Ordinate axis
134 Coordinate origin
136 Stage
138 Stop
140 Stop
142 Coordinate system
144 Abscissa axis
146 Ordinate axis
148 Coordinate origin
150 Image recording unit
152 Image
154 Image
156 Image
158 Image detail
160 Image detail
162 Image detail
164 Rotation
166 Translation
168 Triangle
170 Image
172 Corner
174 Straight line
176 Straight line
200 Examination apparatus
202 Sample
204 Housing
206 Pump
208 Particle beam providing unit
210 Particle beam
212 Electron microscope
214 Sample stage
216 Positioning unit
218 Base
220 Sample stage device
222 Surface
224 Process gas providing unit
226 Process gas
228 Manipulator unit
230 Atomic force microscope
232 Tip
234 Cantilever
236 Positioning unit
238 End
240 End
242 Control device
300 Blank
302 Marker
304 Form
306 Diameter
308 Pattern
310 Grid
312 Interpolation
A1-A3 Location
B, B′ Location
D Defect
Δu Length
Δy Length
Θ Angle
R1-R3 Reference point
P1-P3 Position
P1′-P3′ Position
P_{M} Position
P_{N} Position
\vec{t} Translation vector
tₓ, t_{y} Vector component
S1-S6 Method steps
S1′-S6′ Method steps
S101, S102 Method steps
u Direction, axis
u₁, u₂, u₈ Position
u_{B}, u_{M}, u_{N} Position
v Direction, axis
v₁, v₂, v₈ Position
v_{B}, v_{M}, v_{N} Position
x Direction, axis
x₁, x₂, x₈ Position
x_{B}, x_{N} Position
y Direction, axis
y₁, y₂, y₃ Position
y_{B}, y_{N} Position
z Direction, axis

What is claimed is:

1. A method for examining a blank of a microlithographic photomask, including the steps of:
a) arranging the blank on a first stage of a first examination apparatus such that a first and a second edge of the blank rest against stops of the first stage,
b) ascertaining an examination location on the blank in a first coordinate system with the aid of the first examination apparatus,
c) arranging the blank on a second stage of a second examination apparatus having an image recording unit,
d) recording at least one image of the blank using the image recording unit such that the first and second edge are captured at least in part, and
e) ascertaining a transformation rule on the basis of the first and second edge captured in the at least one image, in order to transform the examination location captured in the first coordinate system into a second coordinate system of the second examination apparatus.

2. The method of claim 1, wherein the second examination apparatus comprises a scanning microscope apparatus, a scanning electron microscope apparatus, a scanning probe microscope apparatus and/or an atomic force microscope apparatus.

3. The method of claim 1, wherein a spatial resolution of the image recording unit of the second examination apparatus is 100 μm or better, 50 μm or better, 30 μm or better, 10 μm or better, 5 μm or better, 1 μm or better, 0.1 μm or better, 50 nm or better, 10 nm or better, 5 nm or better and/or 3 nm or better.

4. The method of claim 1, wherein
one or more defects of the blank are examined in the method,
a location of at least one defect of the blank is ascertained in the first coordinate system in step b) with the aid of the first examination apparatus, and
the ascertained transformation rule serves to transform the location of the at least one defect captured in the first coordinate system into a location in the second coordinate system.

5. The method of claim 4, including after step e):
recording at least one image of the at least one defect using the image recording unit of the second examination apparatus, wherein the image recording unit is aligned on the basis of the location of the at least one defect which has been transformed into the second coordinate system.

6. The method of claim 1, wherein
the first stage) comprises a first, second and third stop,
the blank is arranged on the first stage in such a way that the first edge rests against the first and second stop and the second edge rests against the third stop such that a first, second and third reference point of the blank are defined accordingly at contact locations of the first, second and third stops on the first and second edge,
an image of the blank is recorded in step d) for each reference point, the corresponding reference point being captured in the image, and
the transformation rule is ascertained on the basis of the first, second and third reference points captured in the recorded images.

7. The method of claim 6, wherein
positions of the first and the second reference point in the second coordinate system are ascertained on the basis of image processing for the corresponding recorded images, and/or
a position of the third reference point in the second coordinate system is ascertained on the basis of image processing for the corresponding recorded image.

8. The method of claim 7, wherein
the transformation rule includes a rotation through a rotation angle and/or a translation with a translation vector), and
the rotation angle is ascertained on the basis of the ascertained position of the first and second reference point in the second coordinate system, and/or
vector components of the translation vector are ascertained on the basis of the ascertained position of the third reference point in the second coordinate system and the ascertained position of the first or second reference point in the second coordinate system.

9. The method of claim 7, wherein
the transformation rule includes a transformation matrix according to the following equation:
$$( \begin{matrix}x \\ y \\ 1\end{matrix} ) = ( \begin{matrix}cos Θ & - sin Θ & {t}_{x} \\ sin Θ & cos Θ & {t}_{y} \\ 0 & 0 & 1\end{matrix} ) ( \begin{matrix}u \\ v \\ 1\end{matrix} ) ,$$
where u and v denote coordinates of a location in the first coordinate system, x and y denote coordinates of a location in the second coordinate system, Θ denotes a rotation angle of a rotation of the first coordinate system relative to the second coordinate system, and tₓ and t_{y} denote a translation of the first coordinate system relative to the second coordinate system, and/or
the transformation rule includes a rotation through a rotation angle Θ, which satisfies the following equation:
$$tan Θ = \frac{Δ y}{Δ x} ,$$
where Θ denotes a rotation angle of a rotation of the first coordinate system relative to the second coordinate system, Δx denotes a difference in the abscissa coordinates of the first and second reference point in the second coordinate system, and Δy denotes a difference in the ordinate coordinates of the first and second reference point in the second coordinate system.

10. The method of claim 6, wherein the ascertainment of the transformation rule includes an ascertainment of a coordinate origin of the first coordinate system on the basis of the conditions that
the coordinate origin of the first coordinate system is located on a first straight line on which the first and the second reference point are also located, and
the first straight line is arranged perpendicular to a second straight line, on which the coordinate origin of the first coordinate system and the third reference point are located.

11. The method of claim 1, wherein
the method includes prior to step a):
arranging the blank on the second stage of the second examination apparatus, and
using the second examination apparatus to create a plurality of markers on the blank in accordance with predetermined nominal positions as per the second coordinate system,
ascertaining positions of the plurality of markers in the first coordinate system in step b) with the aid of the first examination apparatus, and
ascertaining a correction rule serving to correct the transformation rule in step e) on the basis of a deviation between the positions of the markers in the first coordinate system ascertained with the aid of the first examination apparatus and the nominal positions of the markers in the second coordinate system.

12. The method of claim 11, wherein the plurality of markers are created by particle beam-induced deposition and/or etching and/or by embossing on the blank.

13. The method of claim 11, wherein the plurality of markers have a circular form and/or a diameter of 10 nm or more, 50 nm or more, 100 nm or more and/or 300 nm or more.

14. The method of claim 11, wherein the plurality of markers are created in a regular pattern and/or regular grid or in an irregular pattern on the blank.

15. The method of claim 11, wherein one or more defects of the blank are examined in the method, and a position of a defect arranged between the created markers is ascertained by interpolating the positions of the markers ascertained by the first examination apparatus.

16. The method of claim 2, wherein a spatial resolution of the image recording unit of the second examination apparatus is 100 μm or better.

17. The method of claim 2, wherein
one or more defects of the blank are examined in the method,
a location of at least one defect of the blank is ascertained in the first coordinate system in step b) with the aid of the first examination apparatus, and
the ascertained transformation rule serves to transform the location of the at least one defect captured in the first coordinate system into a location in the second coordinate system.

18. The method of claim 2, wherein
the first stage) comprises a first, second and third stop,
the blank is arranged on the first stage in such a way that the first edge rests against the first and second stop and the second edge rests against the third stop such that a first, second and third reference point of the blank are defined accordingly at contact locations of the first, second and third stops on the first and second edge,
an image of the blank is recorded in step d) for each reference point, the corresponding reference point being captured in the image, and
the transformation rule is ascertained on the basis of the first, second and third reference points captured in the recorded images.

19. The method of claim 2, wherein
the method includes prior to step a):
arranging the blank on the second stage of the second examination apparatus, and
using the second examination apparatus to create a plurality of markers on the blank in accordance with predetermined nominal positions as per the second coordinate system,
ascertaining positions of the plurality of markers in the first coordinate system in step b) with the aid of the first examination apparatus, and
ascertaining a correction rule serving to correct the transformation rule in step e) on the basis of a deviation between the positions of the markers in the first coordinate system ascertained with the aid of the first examination apparatus and the nominal positions of the markers in the second coordinate system.

20. The method of claim 3, wherein
the method includes prior to step a):
arranging the blank on the second stage of the second examination apparatus, and
using the second examination apparatus to create a plurality of markers on the blank in accordance with predetermined nominal positions as per the second coordinate system,
ascertaining positions of the plurality of markers in the first coordinate system in step b) with the aid of the first examination apparatus, and
ascertaining a correction rule serving to correct the transformation rule in step e) on the basis of a deviation between the positions of the markers in the first coordinate system ascertained with the aid of the first examination apparatus and the nominal positions of the markers in the second coordinate system.
